(19) United States
(12) Patent Application Publication
(10) Pub. No.: US 2026/0254444 A1
(43) Pub. Date: Aug. 27, 2026

(54) POLAR DIGITAL FREQUENCY MODULATOR

(71) Applicant: Commissariat à l'Energie Atomique et aux Energies Alternatives, Paris (FR)

(72) Inventor: David LACHARTRE, Grenoble Cedex 9 (FR)

(73) Assignee: Commissariat à l'Energie Atomique et aux Energies Alternatives, Paris (FR)

(21) Appl. No.: 19/549,249

(22) Filed: Feb. 25, 2026

(30) Foreign Application Priority Data
Feb. 25, 2025 (FR) FR2501920

(51) Int. Cl. H03K 5/131; H03K 5/135

(52) U.S. Cl. CPC H03K 5/131; H03K 5/135

(57) ABSTRACT

A modulator comprising at least two channels arranged in parallel, each channel receiving respectively, as input, a channel clock signal, each channel being able to delay the channel clock signal in order to generate a modulated channel signal according to channel delay control data; an input logic circuit receiving as input a master clock signal as well as normalized frequency samples, and capable of generating channel clock signals and channel delay control data; and an output logic circuit receiving as input each modulated channel signal and capable of generating a frequency modulated output signal from their combination.

### TECHNICAL FIELD

The present invention, which belongs to the field of signal processing, concerns in particular the transmission of digital data over a communication channel via an angular modulation.

Specifically, the present invention relates to a polar digital frequency modulator which may, for example, be advantageously implemented in any radio transmitter transmitting digital data, or in high-precision frequency synthesizers.

The present application also relates to a modulation method implemented by the polar digital frequency modulator of the invention.

### PREAMBLE

Digital data transmissions involving angular modulation generally consist in transmitting successive series of bits represented by the transmitter in the forms of symbols (or phase symbols) to which are associated respectively phase point values (case of phase modulation) or phase variations (case of frequency modulation) intended to generate a modulated signal to be transmitted from a regular periodic signal (hereafter also referred to as carrier) having a fixed frequency F_{c} (referred to as the carrier frequency).

It is established that Cartesian phase modulation, based on the Cartesian representation of the phase on the trigonometric circle and on the generation of analog signals, has several drawbacks, some of which being recalled in the French patent application published under number FR3100404 A1.

As an alternative to the Cartesian phase modulation, the polar phase modulation, which consists in directly modulating the phase (without going through its Cartesian representation on the trigonometric circle) of the carrier, provided various advantages, notably in that it relies mainly on logic blocks and therefore on binary logic signals.

For example, both the carrier and the modulated signal may be, in the case of the polar phase modulation, binary logic signals which are inherently easier to process than the analog signals on which the Cartesian phase modulation is based.

Among the existing polar phase modulation techniques, the one consisting in directly applying the phase symbols to a single clock signal (acting as the carrier) by means of a variable delay block (logic circuit) is interesting in that it establishes the following linear relationship between the delay T_{f} applied to the clock signal and the phase shift φ:

Tᵣ=φ/(2π·F_{c}).

However, applying each phase symbol to the carrier over the entire symbol period T_{sy}, (T_{sy}=1/F_{sy}, F_{sy} being the symbol frequency representing the number of symbols transmitted per second) unfortunately results in excessively abrupt phase transitions between two adjacent symbols and therefore the generation of high frequencies exceeding the frequencies theoretically available to the transmitter.

Therefore, it is appropriate to sample the phase at a sampling frequency Fₛ at least twice the symbol frequency (Fₛ>2·F_{sy}) in order to ensure smooth and gradual transitions between the symbols and thus avoid the emission of high spurious frequencies.

Furthermore, due to the binary nature of the carrier (clock signal), the phase samples are applied to the carrier clock only during the transitions between the high and low logic levels (and vice versa), that is to say during the falling edges and the rising edges of the carrier clock, and a desynchronization between the sampling frequency Fₛ and the carrier frequency F_{c} may therefore lead to random and hardly predictable shifts between the application of the phase samples and their effective action on the carrier clock.

To prevent the occurrence of these undesirable shifts, it is necessary for the sampling frequency Fₛ to be synchronous with the carrier frequency F_{c}. In practice, Fₛ must be at least equal to F_{c} and an optimal value of F_{c} corresponds in particular to 2·F_{c}.

As a general rule, the existing digital modulators allow efficient phase modulations as long as the phase samples to be applied do not exceed 2π (that is to say, 360°) and the phase does not have excessively abrupt variations from one sample to the next.

That being said, and as can be seen in FIGS. 3 and 4, certain existing modulators generate a modulated signal with an incorrect frequency as soon as the phase samples fall outside the interval [0; 2π [and/or when large phase jumps occur that are not smoothed by sampling.

Such errors in the frequency of the modulated signal necessarily result in an incoherent time shift on this signal and therefore in errors in the carried phase information, and thus drastically decrease the quality of the transmission over the communication channel.

However, the frequency modulation, which is based not on phase point values but on phase variations, is not inherently limited to phase samples whose value would be comprised within the interval [0; 2π[.

Furthermore, providing a modulator that supports abrupt phase variations obviously makes it possible to increase the symbol frequency F_{sy} and therefore ultimately the bit rate that can be reached by the transmitter equipped with such a modulator.

There is therefore a need to provide a polar digital modulator that is compatible with the frequency modulation and make it possible to reach high bit rates in transmission.

### SUMMARY OF THE INVENTION

The invention aims to remedy all or part of the aforementioned drawbacks.

In particular, the invention relates, according to a first aspect, to a modulator comprising:
At least two channels disposed in parallel, each channel receiving respectively as input a channel clock signal, each channel being capable of delaying the rising and/or falling edges of the channel clock signal in order to generate a modulated channel signal as a function of respective channel delay control data;
An input logic circuit receiving as input a master clock signal with frequency as well as frequency samples, and capable of generating the channel clock signals from the master clock signal, and of generating the channel delay control data as a function of the normalized frequency samples freq;
An output logic circuit receiving as input each modulated channel signal and capable of generating a frequency-modulated output signal resulting from the combination of the modulated channel signals.

According to one possibility, each of said channels comprises at least one delay cell capable of delaying the rising edges and/or the falling edges of the channel clock signal received as input.

Arranging in parallel several channels provided with at least one delay cell, and combining at the output the modulated channel signals makes it possible to ditribute the rising and falling edges among the channels, and therefore among the delay cells, and thus multiplying the frequency of the modulated output signal by as many as there are channels in parallel, while reducing the frequency of each channel clock signal.

The invention therefore makes it possible to reach, in a consistent manner, high carrier frequencies without the frequency of the channel clock signal applied at the input of each channel, and therefore delayed by at least one delay cell, being high.

According to one possibility, the delay cells comprised in the parallel channels of the modulator are all identical.

According to one possibility, each of the delay cells comprises at least one capacitor.

According to one possibility, the at least one capacitor is connected to a switching element, for example a switch or a commutator.

According to another possibility, each of the delay cells comprises at least one transistor, and for example at least one MOS transistor.

According to one possibility, the modulator is a polar digital frequency modulator that acts directly on the carrier clock signal, which is a binary digital signal that can have two levels: a high level, and a low level, and which has transitions between said levels in the form of rising edges (to go from the low level to the high level) and falling edges (to go from the high level to the low level).

According to one possibility, the master clock signal has a frequency whose value corresponds to twice that of the carrier frequency of the modulator.

According to one possibility, the frequency samples are provided to the input logic circuit at the rate of a sampling clock signal whose frequency is lower than the carrier frequency of the modulator.

According to one embodiment, the number of channels is odd.

According to one possibility, the modulator comprises at least three channels disposed in parallel.

According to one embodiment, the output logic circuit comprises an “exclusive or” logic gate.

According to one possibility, the logic gate generates at the output the modulated output signal by carrying out the combinaison of all the rising and falling edges of each modulated channel signal.

According to one embodiment, each channel comprises at least two identical delay cells mounted in series and capable of delaying the rising and/or falling edges of the channel clock signal as a function of cell delay control data.

Cascading several delay cells on each of the channels makes it possible to increase the modulation dynamic range, that is to say to increase the delay delta (that is to say the difference between the maximum delay and the minimum delay applied by the channel) produced by the set of delay cells. In other words, this makes it possible to increase the possible delays, the phase deltas, and therefore the modulation frequencies accessible to the modulator.

According to one possibility, the delay cells of a same channel are identical.

According to one possibility, all the delay cells of the modulator are identical.

According to one embodiment, the number R of delay cells per channel is a power of 2.

According to one embodiment, the number R of delay cells per channel satisfies:

$$R > \frac{1}{{F}_{clk} ( {T}_{dmax} - {T}_{dmin} )}$$

where T_{dmin} and T_{dmax} are respectively the minimum delay and the maximum delay applicable by each of the delay cells.

According to one embodiment, each delay cell of a same channel is associated with a single digital calculation block capable of generating the cell delay control data intended for the delay cell with which it is associated as a function of the channel delay control data.

According to one possibility, each digital calculation block generates the cell delay control data intended for the delay cell with which it is associated by means of sampling the channel delay control signal received at its input, which comprises the channel delay control data.

According to one possibility, said sampling is carried out through the channel clock signal delayed by said delay cell.

According to these provisions, the cell delay control data received by a delay cell of a given channel are distinct from the cell delay control data received by each of the other delay cells of this same channel.

This makes it possible to increase the maximum frequency of the channel clock signal, since the maximum delay applicable by the series of cells of the channel is no longer a constraint acting on said frequency.

According to one embodiment, the input logic circuit comprises a frequency correction circuit capable of implementing a correction function for the normalized frequency samples freq in order to obtain corrected frequency samples as follows:

$${freq}^{′} = \frac{- freq \cdot {2}^{{N}_{f}}}{freq + {2}^{{N}_{f}}}$$

Advantageously, this frequency correction circuit makes it possible to correct the phase jumps applied by the modulator by moving from the time domain to the frequency domain of the modulated signal generated at the output of the modulator.

According to one embodiment, the input logic circuit comprises as many calculation channels as there are channels included in the modulator, each calculation channel being associated with one of said channels and generating the channel clock signal and the channel delay control data intended for the channel with which it is associated.

According to one embodiment, each calculation channel comprises a first sub-channel dedicated to the calculation of the delay applied to the rising edges of the master clock signal and a second sub-channel dedicated to the calculation of the delay applied to the falling edges of the master clock signal.

According to one embodiment, the modulator further comprises a calibration channel.

According to one possibility, the modulator comprises a single calibration channel intended to carry out the calibration of the delays applied by each of the channels of the modulator.

According to a second aspect, the invention relates to a polar frequency modulation method implemented by a modulator as described above, the method comprising:
A step of generating, by the input logic circuit of the modulator, channel clock signals from a master clock signal received at the input of the input logic circuit of the modulator;
A step of generating the channel delay control data, by the input logic circuit of the modulator, as a function of the normalized frequency samples freq received at the input of the input logic circuit of the modulator;
A step of generating the modulated channel signals from the channel clock signals and as a function of the channel delay control data:
A step of generating the modulated output signal, by the output logic circuit of the modulator, by combining the modulated channel signals.

Thus, the modulator makes it possible to modulate on a carrier frequency a sampled frequency fᵢ such that freq=(fᵢ/F_{c})*2^{Nf}, with N_{f}+1 being the number of bits of the normalized frequency modulation samples freq.

According to one possibility, the carrier frequency corresponds to half of the frequency of the master clock signal.

According to one possibility, the frequency samples are received at the rate of a sampling clock signal whose frequency is lower than the carrier frequency.

### BRIEF DESCRIPTION OF THE FIGURES

The invention will be better understood, and its principles and advantages better apprehended and highlighted, upon reading the detailed description below, made with reference to the figures, among which:

FIG. 1 is a timing diagram representing a modulated signal S(t) obtained via a phase modulation applied to a clock signal P(t).

FIG. 2 is a timing diagram representing a modulated signal S(t) obtained via a phase modulation with sampling applied to a clock signal P(t).

FIG. 3a and FIG. 3b respectively illustrate the error on the frequency of the modulated signal S(t) and the shift introduced by the sampling of the phase relative to a modulated and unsampled signal.

FIG. 4 is a diagram representing two curves illustrating the controlled delay introduced by a delay cell on a rising edge and a falling edge of the clock, respectively, as a function of the binary control of the cell.

FIG. 5 is a schematic diagram of a modulator according to a first embodiment of the invention.

FIG. 6 is a diagram representing the series cascading of the delay cells in one of the channels of the modulator in FIG. 5.

FIG. 7 is a detailed diagram of the association of a delay cell with a local logic block.

FIG. 8a is a timing diagram illustrating the operating principle of the modulator of FIG. 5 applying a fixed frequency modulation of −500 MHz on a carrier frequency F_{c}=1 GHz.

FIG. 8b is a timing diagram illustrating the operating principle of the modulator of FIG. 5 applying a fixed frequency modulation of +500 MHz on a carrier frequency F_{c}=1 GHz.

FIG. 8c is a timing diagram illustrating the frequency modulation according to the invention.

FIG. 8d is a curve that represents the frequency correction function normalized by Fe.

FIG. 9 is a diagram of a first exemplary embodiment of the clock generation and delay calculation block of the modulator of FIG. 5.

FIG. 10a is a diagram of a second exemplary embodiment of the clock generation and delay calculation block of the modulator of FIG. 5, taking into account the modulo.

FIG. 10b is a diagram of a sub-channel for clock generation and delay calculation of the block of FIG. 10a.

FIG. 11a is a schematic diagram of a modulator according to a second embodiment of the invention, including calibration.

FIG. 11b represents a truth table of a phase comparator implemented within the modulator of FIG. 11a.

FIG. 12a to FIG. 12c are three exemplary embodiments of a delay cell used in the modulators of FIGS. 5 and 11.

FIG. 13 is an exemplary embodiment of a 3-bit to 7-bit thermometric decoder used in the delay cell of FIG. 12a.

FIG. 14 is a timing diagram of a signal generated by a so-called “chirp” frequency synthesizer.

FIG. 15 is a schematic diagram of a “chirp” frequency synthesizer implementing the modulator of the invention.

FIG. 16 represents a logic circuit capable of carrying out the division of a clock signal by an integer.

FIG. 17 represents a D flip-flop circuit active on both clock edges.

### DETAILED DESCRIPTION

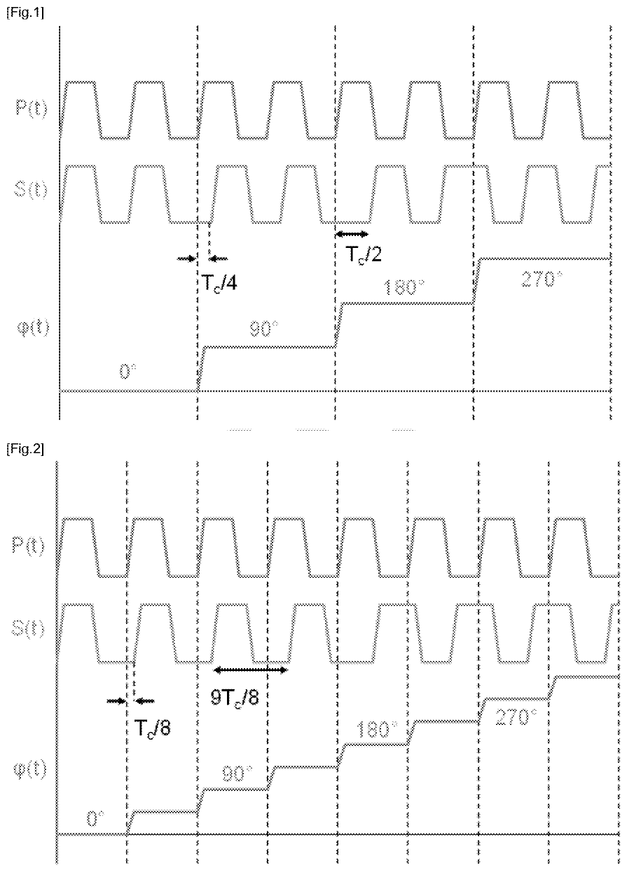

FIGS. 1 to 4 first allow a better understanding of the principles of polar phase modulation, as well as the drawbacks and limitations of existing modulators.

FIG. 1 shows a modulated signal S(t) obtained via a phase modulation applied to a carrier clock signal P(t) with frequency F_{c}. The phase φ(t) corresponds to a series of digital data in the form of a sequence of phase symbols varying over time, which are successively and directly applied to the carrier clock signal P(t) at a symbol frequency F_{sy}.

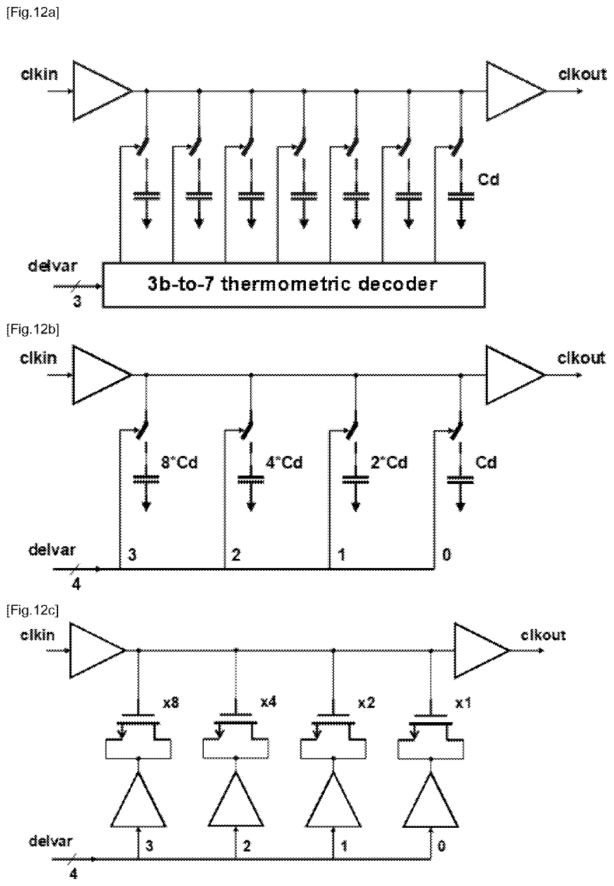

The variable phase values are applied to the carrier clock signal P(t) by means of a digital variable delay block, comprising for example at least one delay cell as illustrated in FIG. 12a, capable of delaying the rising edges of the signal P(t) by a variable delay Tᵣ(t)=φ(t)/(2π·F_{c}).

Such a digital variable delay block is generally a logic circuit capable of transmitting a digital signal received at its input with a variable delay corresponding to a propagation time within the logic circuit of the digital signal received as input, said propagation time varying with the capacitive load at the output of the logic circuit.

By default, each phase symbol is applied to the carrier clock for the entire symbol period: T_{sy}=1/F_{sy}, so that when the symbol changes, the phase applied to the carrier clock changes abruptly without transition, which results in the generation of a very high-frequency modulated signal.

In order to avoid excessively abrupt phase transitions between the consecutive phase symbols and thus the generation of excessively high frequencies (which are neither supported nor intended by the modulator), it is desirable to sample the phase φ(t) at a sampling frequency Fₛ at least twice the symbol frequency F_{sy}: Fₛ>2·F_{sy}, in order to obtain additional phase samples to be applied to the carrier clock.

Furthermore, in order to prevent the occurrence of random and unpredictable shifts between the application of the phase samples and their effective action on the carrier clock and thus the generation of unwanted noise by the modulator, it is imperative that the sampling frequency Fₛ be synchronized with the carrier frequency F_{c}, and more particularly that the sampling frequency Fₛ be, for example, equal to the carrier frequency F_{c} (as shown in FIG. 2), or that the sampling frequency Fₛ be equal to 2·F_{c} (implying that each rising or falling edge of the carrier clock is delayed by a new phase sample).

Thus, FIG. 2 represents a modulated signal S(t) obtained via a phase modulation applied to a carrier clock signal P(t) with frequency F_{c}, by means of sampling the phase φ(t) at a sampling frequency equivalent to the carrier frequency Fₛ=F_{c}, thereby introducing an intermediate phase sample between two successive phase symbols.

Such phase sampling, by smoothing the phase transitions, therefore makes it possible to obtain a coherent modulated signal at the output when the values of the phase samples remain confined within the interval [0;2π[.

Nevertheless, as we will see below, additional difficulties arise when the phase, although sampled, exceeds the dynamic range from 0 to 2π and/or undergoes large variations (despite the sampling).

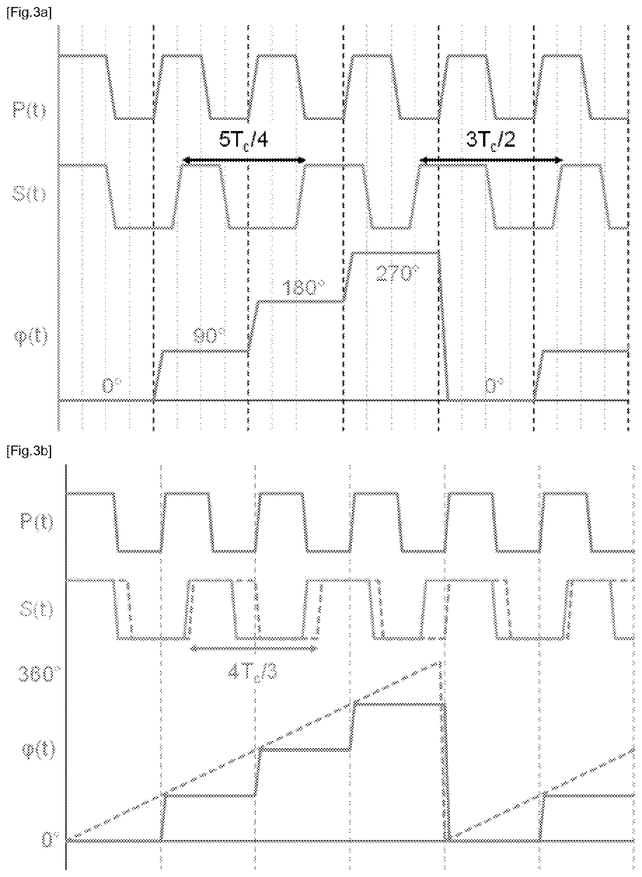

Thus, and as shown in FIGS. 3a and 3b, when the phase φ(t) reaches 2π, it is necessary to apply a modulo 2π operation to return to a zero phase (phase symbol corresponding to 0°) and it is apparent that a problem arises insofar as no rising edge of the clock signal P(t) is transmitted at the output during the corresponding symbol period. In other words, the rising edge of P(t) that has undergone the modulo 2π operation is not propagated to the modulated signal S(t) when transitioning to phase 0°.

Moreover and if one considers a complete cycle of the phase φ(t) from 0 to 2π extending over a time period equivalent to 4·T_{c} (T_{c}=1/F), the modulated signal S(t) has inconsistencies in terms of frequency, and it can indeed be observed that, over this time period equivalent to 4·T_{c}, S(t) carries out only three periods: two first periods equivalent to 5·T_{c}/4 (due to the delays equivalent to Tc/4 which lengthen the period of S(t) compared to that of P(t)) and a third and final period equivalent to 3·T_{c}/2 (since one complete cycle is equivalent to 4·T_{c}=5·T_{c}/4+5·T_{c}/4+3·T_{c}/2).

However, the phase modulation illustrated in FIG. 3a implements constant phase jumps Δφ equivalent to π/2 between two consecutive symbols, and each of these constant phase jumps Δφ theoretically corresponds to a frequency Fᵢ=Δφ/2π·T_{c}=F_{c}/4 which is subtracted from the carrier frequency F_{c} so as to obtain the theoretical frequency of the modulated signal S(t), namely F_{c}−Fᵢ=3·F_{c}/4.

This theoretical frequency 3·F_{c}/4 of the modulated signal S(t) is equivalent to a period of 4·T_{c}/3, which in fact does not correspond to any of the periods of the signal S(t) that can be observed in FIG. 3a (as a reminder 5·T_{c}/4 and 3T_{c}/2). This inconsistency is due to a slipping phenomenon between the period of the phase samples and the period of the signal S(t) generated at the output of the modulator.

The generation of a modulated signal S(t) with erroneous frequencies notably prevents the modulator from properly handling the modulo operation when the phase returns to 0 after reaching 2π, which obviously results in incorrect phase values and therefore in errors in the transmitted information. FIG. 3b clearly illustrates this phenomenon by comparing the signal S(t) (in solid line) of FIG. 3a with a modulated signal (in dotted line) obtained via a continuous-time phase modulation, that is to say a unsampled phase modulation, the latter indeed having a period equivalent to 4·T_{c}/3 and a rising edge synchronized with the rising edge of the carrier clock P(t) upon returning to 0°.

It is known to use digital delay cells such as those shown in FIGS. 12a to 12c to delay a digital signal received at the input of the cell, thus producing at the output a delayed digital signal based on a binary control of the delay cell.

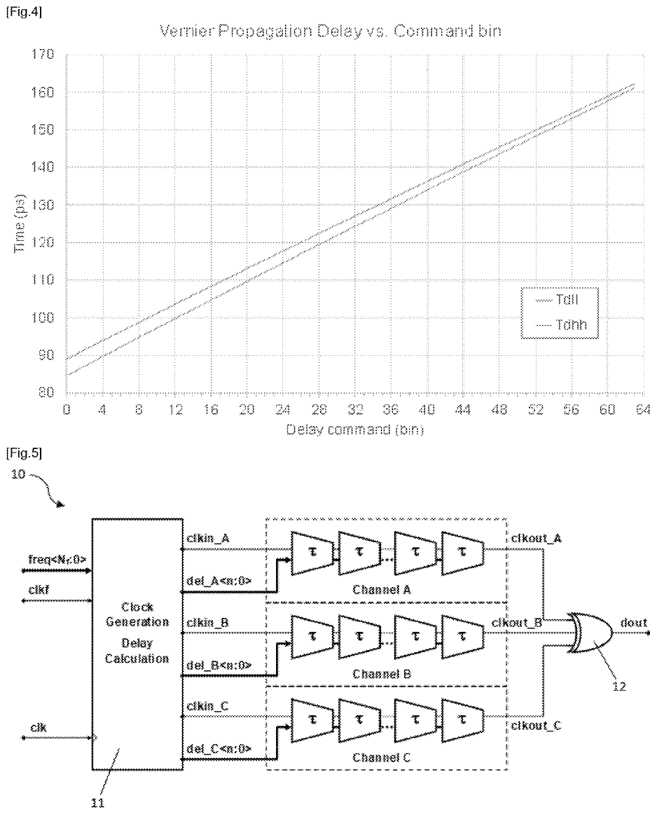

Such delay cells typically delay only one clock edge at a time, either the rising edge or the falling edge. FIG. 4 shows, respectively, as a function of the binary delay control (represented on 6 bits), a first curve representing the value of the delay Tdhh applied to the rising edge of the clock signal, and a second curve representing the value of the delay Tdll applied to the falling edge of the clock signal.

It is noted that such a delay cell is capable of causing delays on control ranging from approximately 90 picoseconds (ps) to 160 ps as a function of the value of the binary control, i.e. a delay delta of approximately 70 ps which in fact corresponds to a phase delta equal to π since a delay cell delays only one clock edge (rising or falling) at a time.

A phase delta of 2π therefore corresponds to a delay delta of approximately 2*70 ps=140 ps. In other words, to be able to modulate over 2π, the carrier frequency must be at least equal to F_{c}=1/140 ps, namely 7.14 GHz.

On the other hand, the delay applied by the delay cell to a single rising/falling clock edge by the delay cell may reach 160 ps, two consecutive edges of the carrier clock applied to the delay cell must therefore be spaced by at least 160 ps. In other words, the period of the carrier clock signal must be at least greater than 320 ps, and its frequency at least less than 3.125 GHz.

It follows from the above that a single delay cell is not sufficient to carry out a phase modulation between 0 and 2π, especially since to ensure the stability of the delay cell, it is necessary that each delay control applied by the cell must be established with a certain pre-positioning time on the clock edge to be effectively delayed, which imposes a carrier frequency value well below 3.125 GHz.

Moreover, arranging two or more identical delay cells in series to delay the carrier clock signal would lead to exactly the same problem, since this would amount to increasing both the delay delta corresponding to 2π and the maximum delay value that can be applied by the set of delay cells to each edge of the carrier clock. This further decreases the possible carrier frequency.

The modulator 10 of FIG. 5 provides a satisfactory solution to the drawbacks described above. It is a polar digital modulator comprising identical delay cells τ, some exemplary embodiments of which are shown in one of FIGS. 12a to 12c.

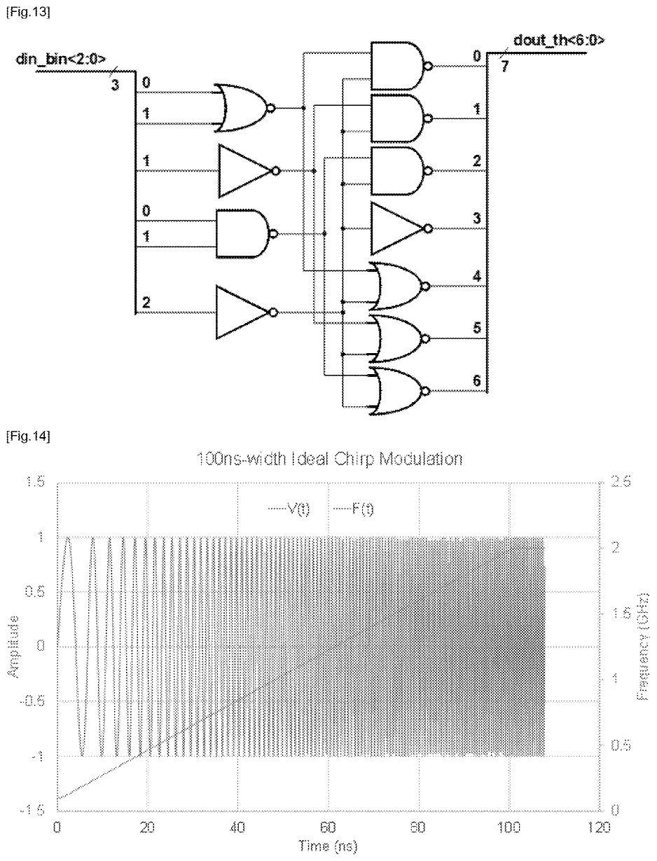

The delay cell shown in FIG. 12a is a digital delay cell (also referred to as a Vernier delay cell or Vernier-type cell) capable of transmitting at the output a signal clkout, delayed relative to a signal clkin received as input and which propagates within the digital delay cell with a non-zero propagation time. Such a digital delay cell is controlled by a 3-bit to 7-bit thermometric decoder, shown in FIG. 13, the operating principles of which are known to those skilled in the art and will not be described in further detail.

The use of a thermometric decoder to control the delay cell makes it possible to minimize the effects due to the dispersion in the values of the capacitors used to carry out the clock delay.

The control provided by the thermometric decoder, by acting on the open or closed position of switches, makes it possible to connect a greater or smaller number of capacitors, connected in series, to the delay cell, which will have the effect of increasing or reducing the propagation time of the signal clkin within the digital delay cell, and therefore increasing or reducing the delay with which the signal clkout will be generated at the output.

FIG. 12b represents a first variant of a Vernier-type digital delay cell, in which the capacitors are grouped in powers of 2 and directly switched by the bits of a binary control.

FIG. 12c shows a second variant of a digital delay cell in which the capacitors are carried out by means of MOS transistor gates. The capacitance variation at the intermediate node is obtained through the varactor effect of the MOS transistors in which the gate capacitance varies as a function of the bias of the source and of the drain of the transistor.

For an NMOS transistor, this capacitance increases as the source and drain voltage increases. Thanks to this effect, a variable delay is obtained without the need to provide switches at each capacitor. The delay cell of FIG. 12c therefore also makes it possible to obtain a linear delay variation as a function of the control signal, and has the advantage of being more compact than the cells of FIGS. 12a and 12b, which use capacitors.

The modulator 10 has three channels A, B, C disposed in parallel, each of said three channels A, B, C comprising the same number of identical delay cells T mounted in series.
The channel A receives as input a channel clock signal clkin_A and is able to delay the rising edges and/or the falling edges of the channel clock signal clkin_A in order to generate at the output a modulated channel signal clkout_A as a function of channel delay control data del_A.
The channel B receives as input a channel clock signal clkin_B and is able to delay the rising edges and/or the falling edges of the channel clock signal clkin_B in order to generate at the output a modulated channel signal clkout_B as a function of channel delay control data del_B.
The channel C receives as input a channel clock signal clkin_C and is able to delay the rising edges and/or the falling edges of the channel clock signal clkin_C in order to generate at the output a modulated channel signal clkout_C as a function of channel delay control data del_C.

The modulator 10 comprises an input logic circuit 11 receiving as input a master clock signal clk with frequency F_{clk} as well as frequency samples freq, the input logic circuit 11 being capable of generating at the output, from the master clock signal clk, the channel clock signal clkin_A, the channel clock signal clkin_B and the channel clock signal clkin_C, respectively.

The minimum frequency F_{clk} of the master clock signal clk is inversely proportional to the number of channels disposed in parallel in the modulator. More precisely, the frequency F_{clk} of the master clock signal received at the input of the modulator 10 is twice the carrier frequency F_{c}, in order to clock the input logic circuit 11 on a single edge.

The input logic circuit 11 is also capable of generating, as a function of the frequency samples freq, the channel control data del_A, del_B, del_C.

The frequency samples freq, which have N_{f}+1 bits, are provided to the input logic circuit 11 at the rate of a sampling clock signal clkf with frequency F_{f} lower than the carrier frequency F_{c} of the modulator.

The modulator 10 also comprises an output logic circuit 12, in this case an “exclusive or” logic gate, receiving as input each modulated channel signal clkout_A, clkout_B, clkout_C, and capable of generating a frequency-modulated output signal dout resulting from the combination of the modulated channel signals clkout_A, clkout_B, clkout_C.

More precisely, the logic gate generates the modulated output signal dout by carrying out the combination of all the rising and falling edges of said modulated channel signals clkout_A, clkout_B, clkout_C.

The channel A comprises several identical delay cells T disposed in series, each capable of delaying the rising and/or falling edges of the channel clock signal clkin_A as a function of cell delay control data del. In particular, the number of delay cells τ disposed on the channel A is equivalent to a power of 2.

The channel B also comprises several identical delay cells τ disposed in series, each capable of delaying the rising and/or falling edges of the channel clock signal clkin_B as a function of cell delay control data del. In particular, the number of delay cells τ disposed on the channel B is equivalent to a power of 2.

The channel C comprises several identical delay cells τ disposed in series, each capable of delaying the rising and/or falling edges of the channel clock signal clkin_C as a function of cell delay control data del. In particular, the number of delay cells τ disposed on the channel C is equivalent to a power of 2.

The channel delay control data del_A, del_B, del_C are digital controls having n+1 bits and are calculated and then supplied to the delay cells by the input logic circuit 11 at the rate of the channel clock signals clkin_A, clkin_B, clkin_C generated from the master clock signal clk of frequency F_{clk}.

Precisely:
the channel delay control data del_A are supplied at the rate of the channel clock signal clkin_A which has variable durations between two successive edges;
the channel delay control data del_B is supplied at the rate of the channel clock signal clkin_B which has variable durations between two successive edges;
the channel delay control data del_C is supplied at the rate of the channel clock signal clkin_C which has variable durations between two successive edges.

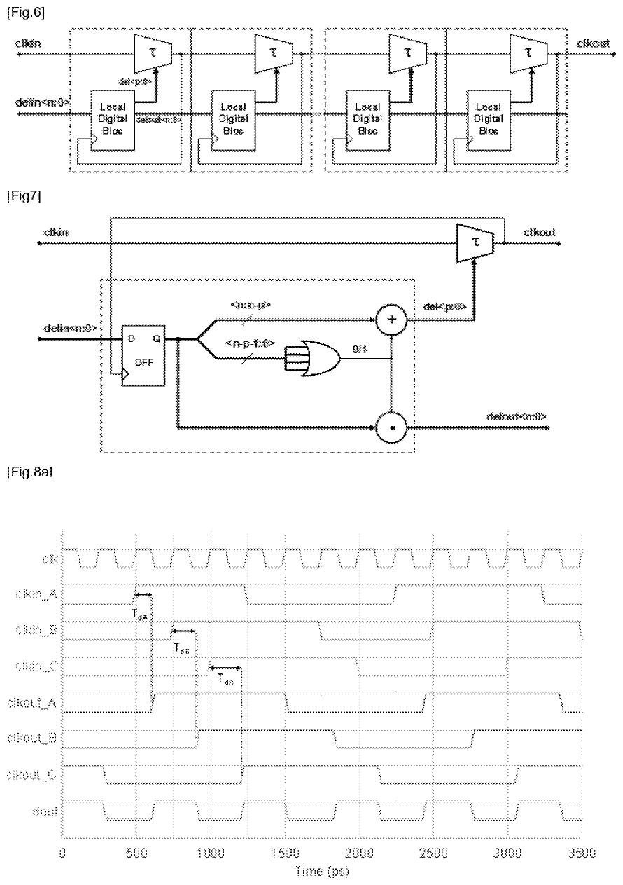

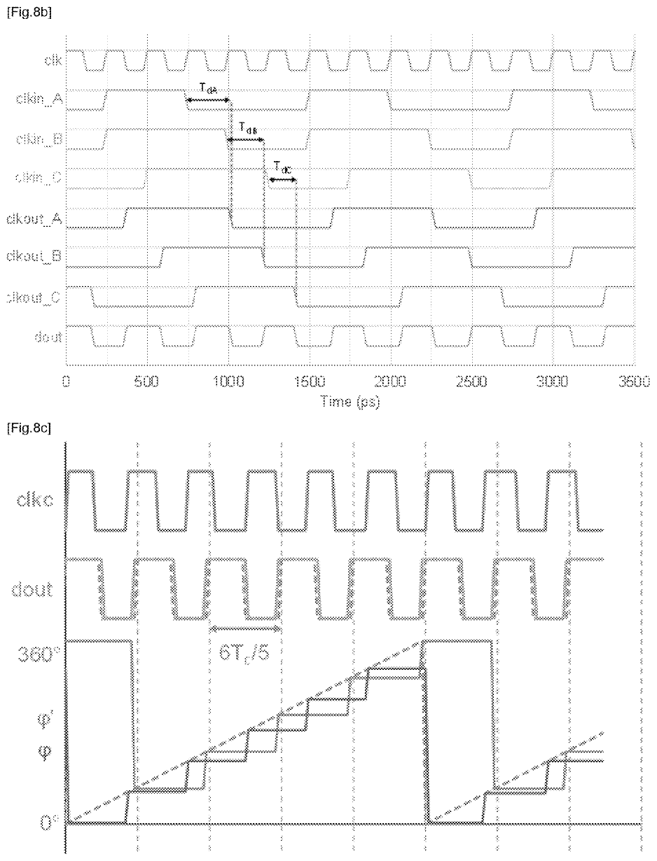

As can be seen in FIGS. 8a and 8b, the channel clock signals clkin_A, clkin_B, clkin_C are synchronous with the rising edges of the master clock signal clk and indeed exhibit variable durations between two edges, that is to say, these channel clocks have variable duty cycles.

Thanks to the odd number of channels, the logic operation performed by the output logic circuit 12 results in the rising edges of the modulated output signal dout always being produced by the rising edges of clkout_A and clkout_C as well as by the falling edges of clkout_B. It will be seen hereinafter that this also provides an advantage in terms of calibration of the modulator.

Conversely, the falling edges are produced by the falling edges of clkout_A and clkout_C as well as the rising edges of clkout_B.

The series arrangement and the operation of the delay cells τ in each of the channels A, B, C are illustrated in a general manner by FIGS. 6 and 7. On each channel A, B, C, each of the delay cells τ is locally associated with a logic calculation block which resamples a channel delay control data delin/delout, encoded on n+1 bits and supplied by the preceding logic calculation block on the corresponding channel.

The resampling is implemented by means of the local clock signal clkout, the input clock clkin having been delayed by the delay cell τ with which the logic calculation block is associated, which ensures that the cell delay control data del, encoded on p+1 bits (p can be different from n, and for example smaller than n), are updated after a clock edge has been delayed, thereby ensuring compliance with the pre-positionning time of the delay control.

The duration of the sampling operation implemented by a logic calculation block is necessarily shorter than the minimum delay that can be applied by each of the delay cells τ of the channel, so that the channel delay control data supplied by the previous logic calculation block on the channel can be sampled by the local clock signal clkout delayed by the delay cell τ.

The resampling of delin in particular implies that each delay cell τ of the given channel receives a cell delay control data del that are distinct from those received by the other delay cells τ of the channel.

This makes it possible to increase the maximum frequency of the channel clock signal clkin since the maximum delay that can be applied by the series of delay cells on a given channel is no longer a constraint acting on said frequency.

The principle of the logic of FIG. 7 consists in performing the integer division of the signal delin by the number of delay cells τ that the channel in question comprises. This integer division is particularly simple to implement when the number of delay cells τ on the channel is a power of 2. This operation then amounts to performing a right shift of the bits of the signal delin. The number of shifts then becomes n−p when the number of cells is R=2^{(n-p)}.

FIG. 7 describes in more detail the association of a delay cell τ with the logic calculation block associated therewith. The signal delin is resampled on both edges of the clock signal clkout by means of D flip-flops as shown in FIG. 17.

The integer division is carried out simply by separating the p+1 most significant bits, which contain the result of the integer division, from the n−p least significant bits, which contain the remainder of the division, of the sampled numerical value of delin. A logic OR gate applied to these bits detects that the remainder of the division is non-zero. In this case, the result of the division is incremented by 1 in order to provide the value del to the corresponding delay cell τ. Likewise, if the remainder of the integer division is non-zero, the value supplied to the next delay cell on the signal delout is decremented by 1. With this mechanism, the different delay values determined by the input logic circuit 11 are distributed over all the delay cells τ of a given channel.

In order to be able to perform a frequency modulation around the carrier frequency Fc, it is necessary that the number R of delay cells τ per channel A, B, C satisfies:

$$R > \frac{1}{{F}_{clk} ( {T}_{dmax} - {T}_{dmin} )}$$

With T_{dmin} is the minimum delay applied by each delay cell τ, T_{dmax} is the maximum delay applied by each delay cell τ, and F_{clk}=2·F_{c}.

For example, the number of delay cells τ per channel must be greater than 4 if F_{clk}=3.6 GHz and if the difference between the maximum delay and the minimum delay applied by each delay cell τ is 70 ps.

The modulator 10 is in particular capable of implementing a modulation of a frequency fᵢ, sampled at the frequency F_{f} of the sampling clock signal clkf, on the carrier frequency F_{c}, in order to generate at the output a frequency-modulated signal. For the modulator 10 to operate correctly in frequency modulation, the absolute value of fᵢ must remain less than F_{c}/2.

An example of such a modulated signal dout is shown in the timing diagram in FIG. 8c, for which F_{f}=F_{c} and fᵢ=−F_{c}/6.

For the frequency fᵢ sampled by the sampling clock signal clkf, the phase is in general given by:

$${φ}_{i} = {φ}_{i - 1} - 2 π \cdot {T}_{f} \cdot {f}_{i}$$

A phase step from one sample to the next that must be accumulated in order to provide the modulated phase is therefore:

$$Δ φ = {ϕ}_{i} - {ϕ}_{i - 1} = - 2 π \cdot {T}_{f} \cdot {f}_{i}$$

In the example of FIG. 8c, the phase steps are, in the time domain (with T_{f}=T_{c} as a reminder): Δφ=π/3.

Since the phase steps are actually applied only at the instants of the rising/falling edges of the modulated signal dout generated at the output of the modulator, it is necessary to correct the phase steps when moving from the time domain to the frequency domain of the modulated signal dout of frequency Fₒᵤₜ=F_{c}+fᵢ=1/Tₒᵤₜ:

$${φ}_{i}^{′} = {φ}_{i - 1}^{′} - 2 π \cdot {T}_{out} \cdot {f}_{i}$$

By linear interpolation of the phase between the clock edges, the phase steps in the frequency domain of the modulated signal dout are therefore:

$$Δ {φ}^{′} = \frac{2 π \cdot {T}_{c} \cdot Δ φ}{2 π \cdot {T}_{f} - {T}_{c} \cdot Δ φ}$$

Thus, in the example of FIG. 8c for which the theoretical modulated frequency is Fₒᵤₜ=F_{c}−F_{c}/6=5F_{c}/6 (and the period of dout: Tₒᵤₜ=6T_{c}/5), the phase steps are equal Δφ=2π/5.

By comparing the modulated signal shown in FIG. 8c with those shown in FIGS. 3a and 3b, it is clear that the modulator 10 of the invention does not introduce errors in the frequency of the modulated signal dout, which in FIG. 8c corresponds to the modulated signal that would be obtained without phase sampling. Thus, the modulator 10 does not exhibit the drawbacks of existing modulators and makes it possible to perform phase or frequency modulation in a coherent manner.

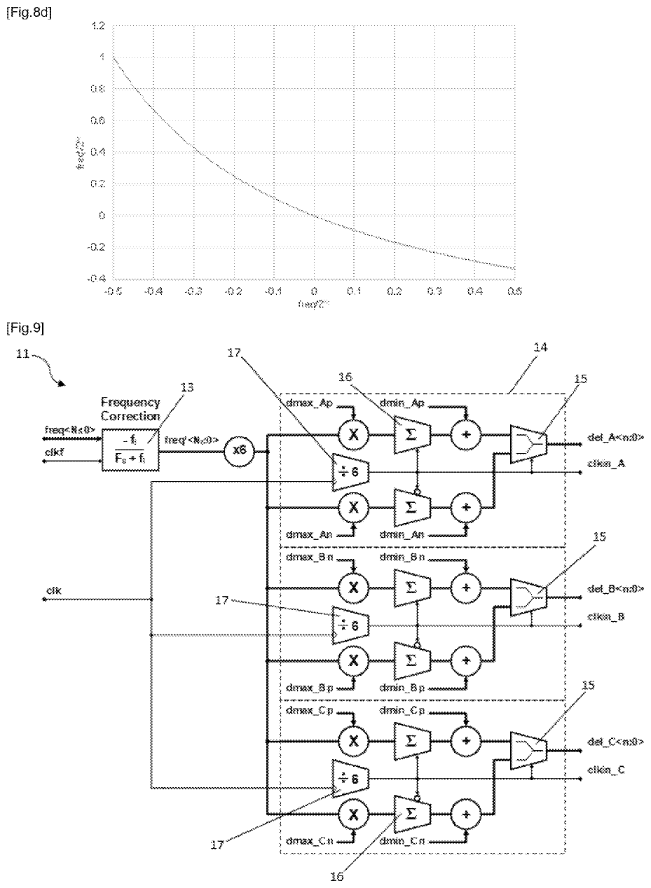

The input logic circuit 11, shown in greater detail in FIG. 9, comprises a frequency correction circuit 13 (frequency corrector) operating at the rate of the sampling clock signal clkf (which may be independent of the master clock signal clk). That is to say, the frequency samples freq are supplied to the input logic circuit 11 at the rate of the sampling clock signal clkf having a frequency F_{f} lower than the carrier frequency F_{c} of the modulator.

This frequency correction circuit 13 produces phase variation samples on freq′ from the normalized frequency samples at the input freq, the normalization of the frequency samples, to be carried out by the user of the modulator 10, consisting in converting the frequency samples fᵢ into binary values on freq such that freq=(fᵢ/F_{c})*2^{Nf} and N_{f}+1 the number of bits of freq.

By analogy with the calculation of the phase steps in the frequency domain of the modulated signal presented above, we have:

$${freq}^{′} = \frac{Δ φ \cdot {T}_{c} \cdot {2}^{{N}_{f}}}{2 π \cdot {T}_{f} - {T}_{c} \cdot Δ φ}$$

With, as seen previously, Δφ=−2π·T_{f}fᵢ, which yields after simplification:

$${freq}^{′} = \frac{- {f}_{i} \cdot {2}^{{N}_{f}}}{{f}_{i} + {F}_{c}}$$

Or, expressed as a fucntion of the digital input frequency:

$${freq}^{′} = \frac{- freq \cdot {2}^{{N}_{f}}}{freq + {2}^{{N}_{f}}}$$

FIG. 8d represents the normalized frequency correction function implemented by the frequency correction circuit 13.

The input logic circuit 11 also comprises a calculation circuit 14 divided into three calculation channels that are identical to one another:
the first calculation channel generates at its output the channel clock signal clkin_A and the channel delay control data del_A.
the second calculation channel generates at its output the channel clock signal clkin_B and the channel delay control data del_B.
the third calculation channel generates at its output the channel clock signal clkin_C and the channel delay control data del_C.

Each calculation channel is further composed of two sub-channels respectively dedicated to the calculations corresponding to the rising edges and the falling edges of the master clock signal.

Thus, and since the modulator 10 comprises three channels A, B, C and since the frequency F_{clk}=2·F_{c}, the channel clock signals clkin_A, clkin_B, clkin_C are generated from the master clock signal clk by clock dividers 17 dividing said clock by six.

The principle diagram of such a clock divider 17 is shown in FIG. 16, which in this instance represents a digital down-counter enabling division of the master clock signal clk by an integer value provided by the digital preset value supplied to one of the inputs of a multiplexer 17.1. A flip-flop register 17.2 which provides at the output a binary signal dcount to a NOR logic gate 17.3. This NOR logic gate 17.3 generates an output signal clkout whose level is equal to 1 when all the bits of the signal dcount are equal to 0, thereby indicating the end of a countdown cycle, and whose level is equal to 0 the rest of the time.

The clock divider 17 further comprises a subtractor 17.4 applying a subtraction of 1 to the signal dcount, and the result of this subtraction is supplied to the multiplexer 17.1, which is further controlled by the signal clkout such that the multiplexer input receiving the preset digital value is selected when the signal clkout is at logic level 1. The output signal of the multiplexer 17.1 is sampled by the flip-flop register 17.2, so that the signal dcount is decremented by 1 at each period of the master clock signal clk as long as the level of the signal clkout is equal to 0. When the level of the signal clkout becomes equal to 1, the flip-flop register 17.2 is pre-positionned with the preset digital value and a new countdown cycle begins.

Once the master clock signal clk is divided by six, each channel clock signal clkin_A, clkin_B, clkin_C presents a logic level which allows, by means of a multiplexer 15 and according to the values of the rising edges or the falling edges, a selection of the channel delay control data del_A, del_B, del_C.

A delay value is calculated from freq′ by multiplying freq′ by 6 and by dmax_y (y=An, Ap, Bn, Bp, Cn, Cp) and then performing an accumulation by means of an accumulator 16. The multiplication by 6 is due to the fact that the accumulation of samples is carried out at the frequency of clkin_x (x=A, B, C) that is to say 6 times slower than the carrier frequency F_{c}.

The value dmax_y is obtained by calibration of the delay channels, which will be explained later. This value dmax_y corresponds to a delay equal to one period of the master clock signal clk, and also corresponds to a phase of π of the carrier F_{c} because the period of the master clock signal clk is equivalent here to T_{c}/2.

At the output of the accumulator 16, the result is added to dmin_y (y=An, Ap, Bn, Bp, Cn, Cp), which is also obtained during the calibration. The value of dmin_y corresponds to the initial delay, that is to say to a phase equal to 0. The accumulator 16 performs the same function as the mathematical integral used to calculate the phase from a frequency. This calculation is carried out here in discrete time, which is made possible by the normalization of freq with respect to F_{c}. It should be noted that the number of bits n+1 of the outputs del_x (x=A, B, C) can be lower than the number of bits N_{f}+1 of freq, without degrading the modulation accuracy.

Since the accumulator 16 in fact performs a phase accumulation, it is necessary to take the modulo into account, in this case a modulo π represented by the value dmax_y (y=An, Ap, Bn, Bp, Cn, Cp) in the case of the modulator 10, said value dmax_y being intended to produce a delay corresponding to T_{c}/2, that is to say, to one period of the master clock signal clk of the modulator 10.

To take the modulo into account, it is necessary to subtract dmax_y when the output of the accumulator 16 reaches or exceeds dmax_y. More generally, it is also necessary to add as many clock edges as the number of modulos thus subtracted.

Conversely, it is necessary to add dmax_y when the output of the accumulator 16 reaches negative values, and in this case to suppress as many clock edges as the number of modulos thus added.

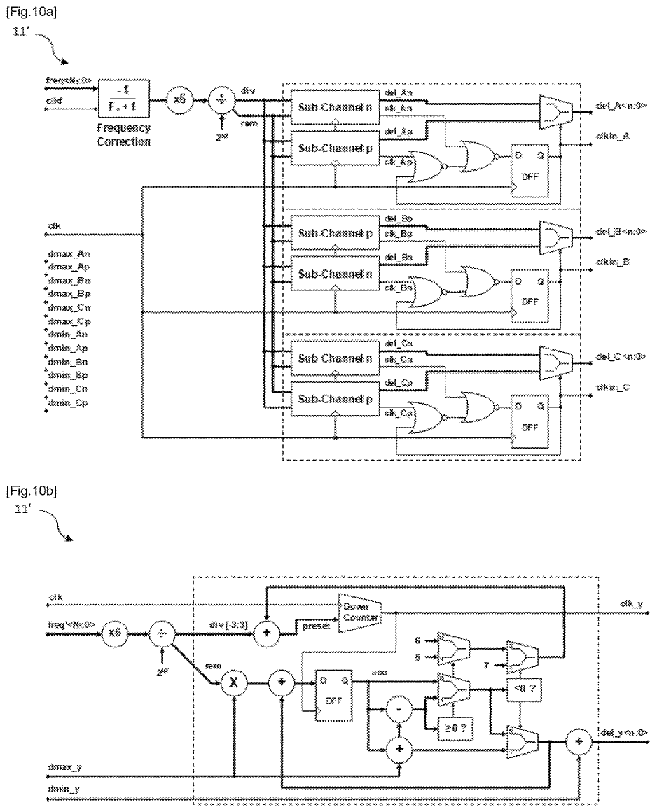

FIG. 10a represents an example of the implementation of the input logic circuit 11′ taking the modulo into account.

More precisely, each of the sub-channels of each calculation channel of the input logic circuit 11 must therefore allow modulo processing when generating the sub-channel clock signal clk_y and the sub-channel delay control data del_y.

The structure and the operation of one of these sub-channels is shown in FIG. 10b, which makes it possible to count the required number of modulos, and thus to adjust the number of periods of the master clock signal clk between two edges of the sub-channel clock signal clk_y that it generates.

In order to add or suppress edges during modulo operations, a down-counter generates a pulse of one period of the master clock signal clk on the output clk_y and loads a new value supplied on preset when it reaches 0. In the absence of modulo, the preset value is 6 and the down-counter behaves as a divide-by-6 clock divider. The value of preset is the sum of two components.

A first preset component is derived from freq′ multiplied by 6 and divided by 2^{Nf} (right shift by N_{f} bits), the result of this signed integer division representing the number of modulos contained in 6 times freq′ (this value being between −3 and 3 in the case of the modulator 10). The remainder of this integer division is multiplied by dmax_y in order to perform the conversion into a calibrated delay increment.

The other preset component is derived from the modulo detection following the accumulation operation and is equal to 6 outside modulo conditions.

The accumulator is formed by an adder and a register whose clock is the signal clk_y. The frequency of the signal clk_y is about 6 times lower than that of the master clock signal clk, which provides more time for the accumulator calculations to be performed.

The modulos are detected by comparing the output of the accumulator acc with the value of dmax_y. When the output of the accumulator acc reaches dmax_y, a selector takes the result of acc−dmax_y, and the preset component changes to 5 and the next edge of clk_y will be closer to one period of clk. When the output of the accumulator acc becomes negative, another selector takes the result of acc+dmax_y, and the preset component changes to 7, making the next edge of clk_y further from the current timescale of clk. Owing to the modulo correction, the delay value is ensured to lie between 0 and dmax_y, to which dmin_y is added to provide del_y.

Thus, the operation of the input logic circuit 11′ taking the modulo into account can be explained, for example, with reference to channel A (the operation for the channel C being identical, the operation for the channel B being similar with inversion of the roles of the n and p sub-channel). Each channel consists of two sub-channels n and p for calculating and generating the channel clock signals corresponding respectively to the rising and falling edges of dout.

When the sub-channel n generates a clock pulse on clk_An, by means of a NOR gate, the D input of the D flip-flop is forced to 0. This flip-flop is clocked by the master clock signal clk. On a rising edge of the master clock signal clk, the Q output goes to 0, thereby generating a falling edge on the channel clock signal clkin_A. Between two pulses, the channel clock signal clkin_A is fed back to the input of a second NOR gate so as to maintain the logic level at the D input of the D flip-flop. When a pulse occurs on clk_Ap, the output of this second NOR gate is forced to 0. Since the clock clk_An had returned to 0, the first NOR gate forces the D input of the flip-flop to 1. On the rising edge of the master clock signal clk, a rising edge is generated on the channel clock signal clkin_A.

A multiplexer allows to select del_Ap when the channel clock signal clkin_A is at logic level 1, or del_An when clkin_A is at logic level 0, and to supply the result on del_A. In this way, for example, a falling edge of the channel clock signal clkin_A can resample the value of del_Ap, which is present on del_A in the first delay cell τ of channel A. The delay value corresponding to rising edges is thus pre-positionned before the arrival of a rising edge of the channel clock signal clkin_A. The opposite occurs for the delay values of falling edges.

The modulator 10 relies on the use of delay cells τ such as those shown in FIGS. 12a to 12c, which are partly analog devices whose delay as a function of their control signals is difficult to predict accurately in particular due to variations in the manufacturing process, inaccuracies in their electrical supply voltage and temperature.

It is therefore necessary, before using the modulator 10, to perform a calibration of the delays actually applied by the delay cells τ of the modulator and thus by each of the channels of the modulator, especially since the result also depends on the frequency of the master clock signal clk. The purpose of the calibration is to adjust the delay actually applied to a desired phase shift.

FIG. 4 further shows that it is necessary to perform a calibration of the delay cells τ for the rising edges and a calibration for the falling edges.

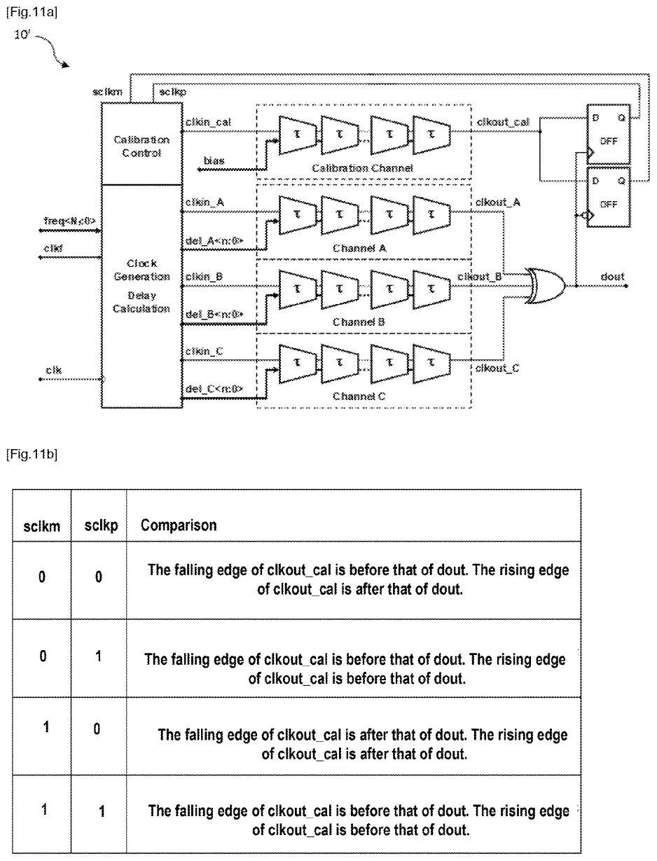

FIG. 11a therefore shows a modulator 10′ in accordance with a second embodiment of the invention, which differs from the modulator 10 in that it further comprises a calibration channel cal specifically dedicated to the calibration of the modulator 10′ in addition to the channels A, B, C.

The calibration method is based on a differential measurement between one of the three channels A, B, C and the calibration channel cal, which is identical to channels A, B, C but has the particular feature of receiving a fixed channel delay control data bias, which is adjusted to be slightly greater than 0 so that none of the other channels A, B, C risk being saturated at 0 during the calibration.

The calibration makes it possible to update the registers dmax_y and dmin_y before using the modulator 10′. All channels and sub-channels are calibrated one after the other. To calibrate a given channel and sub-channel, the clocks clkout_x of the other channels are fixed at the logic levels that these channels would exhibit during modulation at the instant of the considered edge. Thus, at the time of rising edges of clkout_A, the clocks clkout_B and clkout_C are always at 0. Conversely, at the time of rising edges of clkout_B, clkout_A is at 1 while clkout_C is at 0. Owing to this mechanism, during calibration, the propagation times of the edges to the output dout are truly representative of normal modulation operation.

To calibrate one edge of a channel, the digital block generates a fixed clock on clkin_x derived from division of clk. The calibration of an edge begins with the measurement of dmin_y, that is to say the initial delay value. For this purpose, the calibration controller generates on clkin_cal the same clock as that on clkin_x. At startup, the value del_x is initialized to 0 and the objective is for this value to increase until it reaches a value close to bias. For this purpose, a phase comparator device, whose truth table is shown in FIG. 11b, is arranged between dout and the output of the calibration channel clkout_cal. It consists of two D flip-flops that sample clkout_cal, one on the rising edges and the other on the falling edges of dout. The logic levels of the two generated signals sclkm and sclkp make it possible to determine whether dout is leading or lagging with respect to clkout_cal depending on the considered edge.

As long as dout leads clkout_cal, a positive phase error is incremented, filtered, and then applied to del_x. Conversely, the error is decremented when dout lags clkout_cal. When the two clocks are in phase, this loop converges toward the correct delay value. Once the convergence reaches a given accuracy threshold, the value of del_x is stored in the register dmin_y and the calibration proceeds to the next step.

For the measurement of dmax_y, the calibration controller generates on clkin_cal a clock delayed by one period of clk with respect to that present on clkin_x. The process then proceeds in the same manner as for dmin_y, and del_x converges toward the value for which the clocks are in phase. Since clkin_cal has been delayed by one period of clk, in this implementation this corresponds to a phase shift of π with respect to the carrier F_{c}. After convergence, the value del_x−dmin_y is stored in the register dmax_y.

Since all the calibration steps are performed by comparison with a single calibration channel whose bias setting remains unchanged, all channels are calibrated with respect to the same reference and are all calibrated relative to one another.

The invention described above is particularly applicable to so-called «chirp» frequency synthesis, which has the particular feature of producing a rectangular-shaped spectrum in the frequency domain, and in which the time-domain signal undergoes a continuous and linear frequency variation over time between a first frequency F_{ch1} (referred to as the starting frequency) and a second frequency F_{ch2} (referred to as the final frequency) over a given time period T_{ch}.

By observing FIG. 14, which represents in the time domain a signal generated by a so-called «chirp» frequency synthesizer with F_{ch1}=100 MHz, F_{ch2}=2 GHz and T_{ch}=100 ns, it can be understood that the main difficulty posed by the ((chirp modulation for the existing frequency synthesizers is the need to generate a large frequency variation in a very short time (19 GHz/μs).

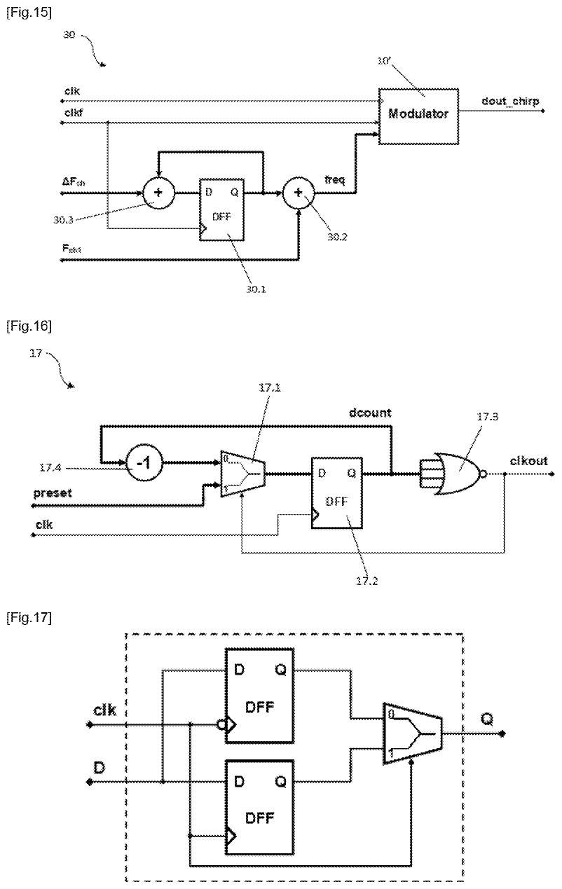

However, the use of the modulator of the invention in a so-called ((chirp frequency synthesizer 30 as shown in FIG. 15 makes it possible to generate reliably and simply at the output a signal dout_chirp similar to the signal shown in FIG. 14. For this purpose, the synthesizer 30 notably comprises a flip-flop register 30.1 clocked by the sampling clock signal clkf, and generates frequency samples freq calculated at the rate of the sampling clock signal clkf from the value of the starting frequency F_{ch1}, which is added to the output of the flip-flop register 30.1 by means of a first adder 30.2, and from the value of the frequency slope ΔF_{ch}=(F_{ch2}−F_{ch1})/T_{ch}, ΔF_{ch} being added to the output of the flip-flop register 30.1 by means of a second adder 30.3 and fed back to the input of the flip-flop register 30.1.

The invention is obviously not limited to the embodiment described in detail above, and encompasses all variants within the abilities of a person skilled in the art. For example, the various messages exchanged between the electronic devices (sensors and actuators) and the control unit may have structures and/or transmission durations different from those defined above.

1. A modulator comprising:
at least two channels arranged in parallel, each channel receiving respectively, as input, a channel clock signal, each channel being configured to delay rising and/or falling edges of the channel clock signal in order to generate a modulated channel signal according to channel delay control data, respectively;
an input logic circuit receiving as input a master clock signal of frequency F_{clk} and normalized frequency samples, and configured to generate channel clock signals from the master clock signal, and generate channel delay control data as a function of the normalized frequency samples; and
an output logic circuit receiving as input each modulated channel signal configured to generate a frequency modulated output signal from a combination of the modulated channel signals.

2. The modulator according to claim 1, wherein a number of channels is odd.

3. The modulator according to claim 1, wherein the output logic circuit comprises an exclusive or logic gate.

4. The modulator according to claim 1, wherein each channel comprises at least two identical delay cells mounted in series and configured to delay the rising and/or falling edges of the channel clock signal according to cell delay control data.

5. The modulator according to claim 4, wherein a number R of delay cells per channel is a power of 2.

6. The modulator according to claim 4, wherein a number R of delay cells per channel satisfies:
$$R > \frac{1}{{F}_{clk} ( {T}_{dmax} - {T}_{dmin} )} ,$$
where T_{dmin} and T_{dmax} are respectively a minimum delay and a maximum delay applicable by each of the delay cells.

7. The modulator according to claim 4, wherein each delay cell of the same channel is associated with a single digital calculating block configured to generate the cell delay control data intended for the delay cell to which the single digital calculating block is associated, as a function of the channel delay control data.

8. The modulator according to claim 1, wherein the input logic circuit comprises a frequency correction circuit configured to implement a correction function for normalized frequency samples so as to obtain frequency corrected samples (freq′) such that:
$${freq}^{′} = \frac{- freq \cdot {2}^{{N}_{f}}}{freq + {2}^{{N}_{f}}} .$$

9. The modulator according to claim 1, wherein the input logic circuit comprises as many calculation channels as there are channels included by the modulator, each calculation channel being associated with one of said channels and generating the channel clock signal and the channel delay control data for the channel associated with calculation channel.

10. The modulator according to claim 9, wherein each calculation channel comprises a first sub-channel configured to calculate the delay applied to rising edges of the master clock signal and a second sub-channel configured to calculate the delay applied to the falling edges of the master clock signal.

11. The modulator according to claim 1, further comprising a calibration channel.

12. A method for polar frequency modulation implemented by the modulator according to claim 1, the method comprising:
generating, by the input logic circuit of the modulator, the channel clock signals from a master clock signal of frequency F_{clk} received at the input of the input logic circuit of the modulator;
generating the channel delay control data, by the input logic circuit of the modulator, as a function of the normalized frequency samples received at the input of the input logic circuit of the modulator;
generating the modulated channel signals from channel clock signals and as a function of the channel delay control data; and
generating the modulated output signal, by the output logic circuit of the modulator, by combining the modulated channel signals.
